(19) United States
(12) Patent Application Publication
(10) Pub. No.: US 2013/0200920 A1
(43) Pub. Date: Aug. 8, 2013

(54) POWER SUPPLY TEST SYSTEM

(71) Applicants: ZHI-YONG GAO, Wuhan City (CN); YUN-FEI ZHANG, Wuhan City (CN); YU-LIN LIU, Wuhan City (CN)

(72) Inventors: ZHI-YONG GAO, Wuhan City (CN); YUN-FEI ZHANG, Wuhan City (CN); YU-LIN LIU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/600,562

(22) Filed: Aug. 31, 2012

(30) Foreign Application Priority Data
Feb. 7, 2012 (CN) 201210026110.6

(51) Int. Cl. G01R 31/42

(52) U.S. Cl. 324/764.01

(57) ABSTRACT

A power supply test system for testing reliability of a power supply includes a voltage input circuit, a voltage storage circuit, a voltage output circuit, and a discharge circuit. The voltage input circuit receives a first AC voltage, and converts the first AC voltage to a first DC voltage to charge the voltage storage circuit. The voltage storage circuit receives the first DC voltage, and discharges to the power supply via the voltage output circuit when the voltage storage circuit is fully charged. The voltage storage circuit discharges remaining voltages via the discharge circuit when the test is complete.

### BACKGROUND

1. Technical Field

The present disclosure relates to a power supply test system for testing reliability of a power supply.

2. Description of Related Art

Computer power supplies are capable of converting alternating current into direct current. The reliability of a power supply is measured by comparing the input and output voltages of the power supplies. Over voltage testing is an important test in determining the reliability of the power supply. A typical over voltage test uses an oscillograph to test a current and a voltage input in the power supply. However, the typical testing method cannot test peripheral circuits in the power supply. Therefore, the over voltage testing is not complete and comprehensive.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a power supply test system.

FIG. 2 is a circuit diagram of the power supply test system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

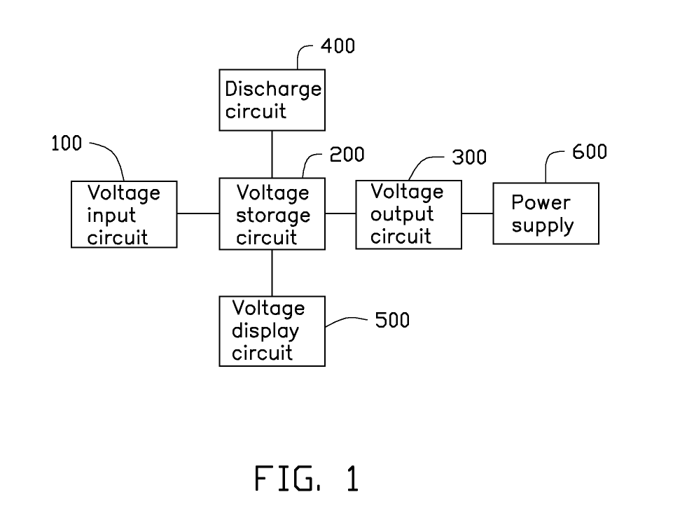

FIG. 1 illustrates a power supply test system in accordance with an embodiment. The power supply test system is adapted to test reliability of a power supply 600 under a high voltage condition. The power supply test system includes a voltage input circuit 100, a voltage storage circuit 200, a voltage output circuit 300, a discharge circuit 400, and a voltage display circuit 500. The voltage input circuit 100 is adapted to receive a first AC voltage, and convert the first AC voltage to a first DC voltage to charge the voltage storage circuit 200. The voltage storage circuit 200 is adapted to receive the first DC voltage, and discharge to the power supply 600 via the voltage output circuit 300 when the voltage storage circuit 200 is fully charged. The voltage storage circuit 200 is adapted to discharge remaining voltages via the discharge circuit 400 when the test is complete. The voltage display circuit 500 is adapted to display a voltage value of the rest voltage in the voltage storage circuit 200 during the charge and discharge process.

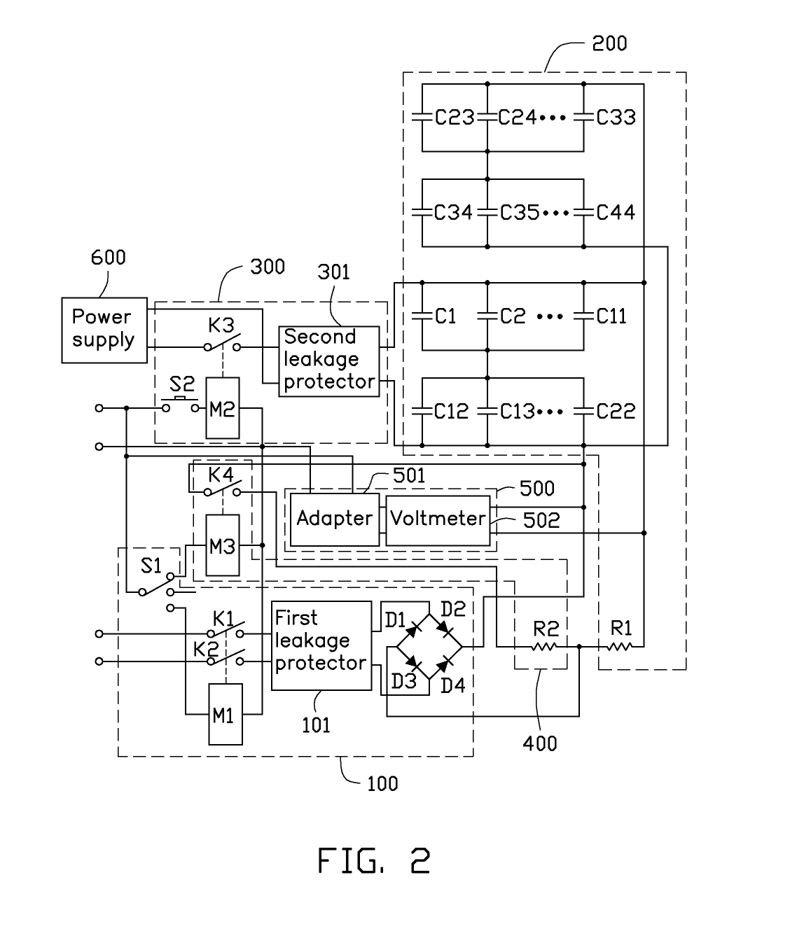

FIG. 2 illustrates the voltage input circuit 100, the voltage storage circuit 200, the voltage output circuit 300, the discharge circuit 400, and the voltage display circuit 500 in accordance with one embodiment. The voltage input circuit 100 includes a multiple switch S1, a first relay, a first leakage protector 101, a first diode D1, a second diode D2, a third diode D3 and a fourth diode D4. The first relay includes a first winding unit M1, a first switch unit K1 and a second switch unit K2. A first terminal of the first switch unit K1 is electrically connected to a live wire output terminal of the first AC voltage. A first terminal of the second switch unit K2 is electrically connected to a neutral wire output terminal of the first AC voltage. Second terminals of the first and second switch units K1 and K2 are electrically connected to input terminals of the first leakage protector 101. A first terminal of the first winding unit M1 is electrically connected to a live wire output terminal of a second AC voltage via the multiple switch S1. A second terminal of the first winding unit M1 is electrically connected to a neutral wire output terminal of the second AC voltage. A cathode of the first diode D1 is electrically connected to an anode of the second diode D2. An anode of the first diode D1 is electrically connected to an anode of the third diode D3. A cathode of the third diode D3 is electrically connected to an anode of the fourth diode D4. A cathode of the fourth diode D4 is electrically connected to a cathode of the second diode D2. Connection points between the first and second diodes D1 and D2, and the third and fourth diodes D3 and D4 are electrically connected to output terminals of the first leakage protector 101 to receive the first AC voltage. Connection points between the first and third diodes D1 and D3, and the second and fourth diodes D2 and D4 outputs the first DC voltage. In one embodiment, the first AC voltage is +274V. The second AC voltage is +220V. The first DC voltage is +380V.

The voltage storage circuit 200 includes a first resistor R1, a plurality of first capacitors C1-C11, a plurality of second capacitors C12-C22, a plurality of third capacitors C23-C33, and a plurality of fourth capacitors C34-C44. Anodes of each of the first capacitors C1-C11 are electrically connected to the connection point between the first and third diodes D1 and D3 via the first resistor R1. Anodes of each of the second capacitors C12-C22 are electrically connected to cathodes of each of the first capacitors C1-C11. Cathodes of each second capacitor C12-C22 is electrically connected to the connection point between the second and fourth diodes D2 and D4. Anodes of the third capacitors C23-C33 are electrically connected to the anodes of the first capacitors C1-C11. Anodes of the fourth capacitors C34-C44 are electrically connected to cathodes of the third capacitors C23-C33. Cathodes of the fourth capacitors C34-C44 are electrically connected to the cathodes of the second capacitors C12-C22.

The voltage output circuit 300 includes a second relay, a second leakage protector 301, and a push button S2. The second relay includes a second winding unit M2 and a third switch unit K3. The anodes of the first capacitors C1-C11 and the cathodes of the second capacitors C12-C22 are electrically connected to input terminals of the second leakage protector 301. A first output terminal of the second leakage protector 301 is electrically connected to the power supply 600. A second output terminal of the second leakage protector 301 is electrically connected to the power supply 600 via the third switch unit K3. A first terminal of the second winding unit M2 is electrically connected to a live wire output terminal of the second AC voltage via the push button S2. A second terminal of the second winding unit M2 is electrically connected to a neutral wire output terminal of the second AC voltage.

The discharge circuit 400 includes a second resistor R2 and a third relay. The third relay includes a third winding unit M3 and a fourth switch unit K4. A first terminal of the third winding unit M3 is electrically connected to the live wire output terminal of the second AC voltage via the multiple switch S1. A second terminal of the third winding unit M3 is electrically connected to the neutral wire output terminal of the second AC voltage. The cathodes of the second capacitors C12-C22 are electrically connected to the connection point between the first and third diodes D1 and D3 via the fourth switch unit K4 and the second resistor R2 connected in series. In one embodiment, the switch units K1-K4 are normally-open contact switches.

The voltage display circuit 500 includes an adapter 501 and a voltmeter 502. Input terminals of the adapter 501 are electrically connected to the live wire output terminal and the neutral wire output terminal of the second AC voltage. Output terminals of the adapter 501 are electrically connected to input terminals of the voltmeter 502. Output terminals of the voltmeter 502 are electrically connected to the anodes of the first capacitors C1-C11 and the cathodes of the second capacitors C12-C22. In one embodiment, the adapter 501 is adapted to convert the +220V second AC voltage to a +5V second DC voltage which is provided to the voltmeter 502.

In a working state, when the +274V first AC voltage charges the voltage storage circuit 200, the multiple switch Si is activated to provide the +220V second AC voltage to the first winding unit M1. The first and second switch units K1 and K2 are closed. The +274V first AC voltage charges the plurality of capacitors C1-C44 via the first leakage protector 101, the diodes D1-D4, and the first resistor R1. The voltage value of the remaining voltages in the voltage storage circuit 200 is displayed on the voltmeter 502. When the voltage storage circuit 200 is charged to +380V, the multiple switch S1 is activated and the push button S2 is pressed to provide the +220V second AC voltage to the second winding unit M2. The third switch unit K3 is closed. The voltage storage circuit 200 discharges the +380V first DC voltage to the power supply 600 via the second leakage protector 301 and the third switch unit K3.

When the test is complete, the multiple switch Si is activated to provide the +220V second AC voltage to the third winding unit M3. The fourth switch unit K4 is closed. The remaining voltages in the plurality of capacitors C1-C44 are exhausted by the first and second resistors R1 and R2. In one embodiment, the first and second leakage protectors 103 and 301 are opened when there is current leakage from the +274V first AC voltage or the +380V first DC voltage.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A power supply test system for testing reliability of a power supply, the power supply test system comprising:
a voltage input circuit for receiving a first AC voltage and converting the first AC voltage to a first DC voltage;
a voltage storage circuit for receiving the first DC voltage and discharging to the power supply when fully charged by the first DC voltage;
a voltage output circuit electrically connected to the voltage storage circuit and the power supply; and
a discharge circuit electrically connected to the voltage storage circuit, wherein the voltage storage circuit discharges to the power supply via the voltage output circuit, and the voltage storage circuit discharges remaining voltages via the discharge circuit when the test is complete.

2. The power supply test system of claim 1, wherein the voltage input circuit comprises a multiple switch, a first relay, a first leakage protector, and a plurality of diodes electrically connected together end to end; the first relay comprises a first winding unit, a first switch unit, and a second switch unit; a first terminal of the first switch unit is electrically connected to a live wire output terminal of the first AC voltage; a first terminal of the second switch unit is electrically connected to a neutral wire output terminal of the first AC voltage; second terminals of the first and second switch units are electrically connected to the voltage storage circuit via the first leakage protector and the plurality of diodes; a first terminal of the first winding unit is electrically connected to a live wire output terminal of a second AC voltage; and a second terminal of the first winding unit is electrically connected to a neutral wire output terminal of the second AC voltage.

3. The power supply test system of claim 2, wherein the voltage storage circuit comprises a first resistor, a plurality of first capacitors, and a plurality of second capacitors; anodes of the plurality of first capacitors are electrically connected to the plurality of diodes via the first resistor; anodes of the plurality of second capacitors are electrically connected to cathodes of the plurality of first capacitors; and cathodes of the plurality of second capacitors are electrically connected to the plurality of diodes.

4. The power supply test system of claim 3, wherein the voltage output circuit comprises a second relay, a second leakage protector, and a push button; the second relay comprises a second winding unit and a third switch unit; the anodes of the plurality of first capacitors and the cathodes of the plurality of second capacitors are electrically connected to input terminals of the second leakage protector; a first output terminal of the second leakage protector is electrically connected to the power supply; a second output terminal of the second leakage protector is electrically connected to the power supply via the third switch unit; a first terminal of the second winding unit is electrically connected to a live wire output terminal of the second AC voltage via the push button; and a second terminal of the second winding unit is electrically connected to a neutral wire output terminal of the second AC voltage.

5. The power supply test system of claim 4, wherein the discharge circuit comprises a second resistor and a third relay; the third relay comprises a third winding unit and a fourth switch unit; a first terminal of the third winding unit is electrically connected to the live wire output terminal of the second AC voltage via the multiple switch; a second terminal of the third winding unit is electrically connected to the neutral wire output terminal of the second AC voltage; and the cathodes of the plurality of second capacitors are electrically connected to the plurality of diodes via the fourth switch unit and the second resistor connected in series.

6. The power supply test system of claim 5, further comprising a voltage display circuit electrically connected to the voltage storage circuit, wherein the voltage display circuit is adapted to display a voltage value of the remaining voltages in the voltage storage circuit during the charge and discharge process.

7. The power supply test system of claim 6, wherein the voltage display circuit comprises an adapter and a voltmeter; input terminals of the adapter are electrically connected to the live wire output terminal and the neutral wire output terminal of the second AC voltage respectively; output terminals of the adapter are electrically connected to input terminals of the voltmeter; and output terminals of the voltmeter are electrically connected to the anodes of the plurality of first capacitors and the cathodes of the plurality of second capacitors respectively.

8. The power supply test system of claim 7, wherein the adapter is adapted to convert the second AC voltage to a second DC voltage which is provided to the voltmeter.

9. The power supply test system of claim 8, wherein the first AC voltage is about +274V, the second AC voltage is about +220V, the first DC voltage is about +380V, and the second DC voltage is about +5V.

10. A power supply test system for testing reliability of a power supply, the power supply test system comprising:
a voltage input circuit for receiving a first AC voltage and converting the first AC voltage to a first DC voltage;
a voltage storage circuit for receiving the first DC voltage, and discharging to the power supply when fully charged by the first DC voltage;
a voltage output circuit electrically connected to the voltage storage circuit and the power supply;
a discharge circuit electrically connected to the voltage storage circuit; and
a voltage display circuit electrically connected to the voltage storage circuit, wherein the voltage storage circuit discharges to the power supply via the voltage output circuit, the voltage storage circuit discharges remaining voltages via the discharge circuit when the test is complete, and the voltage display circuit displays a voltage value of the remaining voltages in the voltage storage circuit during the charge and discharge process.

11. The power supply test system of claim 10, wherein the voltage input circuit comprises a multiple switch, a first relay, a first leakage protector, and a plurality of diodes electrically connected together end to end; the first relay comprises a first winding unit, a first switch unit, and a second switch unit; a first terminal of the first switch unit is electrically connected to a live wire output terminal of the first AC voltage; a first terminal of the second switch unit is electrically connected to a neutral wire output terminal of the first AC voltage; second terminals of the first and second switch units are electrically connected to the voltage storage circuit via the first leakage protector and the plurality of diodes; a first terminal of the first winding unit is electrically connected to a live wire output terminal of a second AC voltage; and a second terminal of the first winding unit is electrically connected to a neutral wire output terminal of the second AC voltage.

12. The power supply test system of claim 11, wherein the voltage storage circuit comprises a first resistor, a plurality of first capacitors, and a plurality of second capacitors; anodes of the plurality of first capacitors are electrically connected to the plurality of diodes via the first resistor; anodes of the plurality of second capacitors are electrically connected to cathodes of the plurality of first capacitors; and cathodes of the plurality of second capacitors are electrically connected to the plurality of diodes.

13. The power supply test system of claim 12, wherein the voltage output circuit comprises a second relay, a second leakage protector, and a push button; the second relay comprises a second winding unit and a third switch unit; the anodes of the plurality of first capacitors and the cathodes of the plurality of second capacitors are electrically connected to input terminals of the second leakage protector; a first output terminal of the second leakage protector is electrically connected to the power supply; a second output terminal of the second leakage protector is electrically connected to the power supply via the third switch unit; a first terminal of the second winding unit is electrically connected to a live wire output terminal of the second AC voltage via the push button; and a second terminal of the second winding unit is electrically connected to a neutral wire output terminal of the second AC voltage.

14. The power supply test system of claim 13, wherein the discharge circuit comprises a second resistor and a third relay; the third relay comprises a third winding unit and a fourth switch unit; a first terminal of the third winding unit is electrically connected to the live wire output terminal of the second AC voltage via the multiple switch; a second terminal of the third winding unit is electrically connected to the neutral wire output terminal of the second AC voltage; and the cathodes of the plurality of second capacitors are electrically connected to the plurality of diodes via the fourth switch unit and the second resistor connected in series.

15. The power supply test system of claim 14, wherein the voltage display circuit comprises an adapter and a voltmeter; input terminals of the adapter are electrically connected to the live wire output terminal and the neutral wire output terminal of the second AC voltage respectively; output terminals of the adapter are electrically connected to input terminals of the voltmeter; and output terminals of the voltmeter are electrically connected to the anodes of the plurality of first capacitors and the cathodes of the plurality of second capacitors respectively.

16. The power supply test system of claim 15, wherein the adapter is adapted to convert the second AC voltage to a second DC voltage which is provided to the voltmeter.

17. The power supply test system of claim 16, wherein the first AC voltage is about +274V, the second AC voltage is about +220V, the first DC voltage is about +380V, and the second DC voltage is about +5V.
